(19) United States
(12) Patent Application Publication
(10) Pub. No.: US 2023/0061262 A1
(43) Pub. Date: Mar. 2, 2023

(54) DEVICE FOR COOLING AN ELECTRICAL AND/OR ELECTRONIC COMPONENT LIABLE TO RELEASE HEAT DURING OPERATION

(71) Applicant: VALEO SYSTEMES THERMIQUES, La Verriere (FR)

(72) Inventors: Sergio DA COSTA PITO, La Verriere (FR); Bastien JOVET, La Verriere (FR); Quentin NAVARRE, La Verriere (FR)

(73) Assignee: VALEO SYSTEMES THERMIQUES, La Verriere (FR)

(21) Appl. No.: 17/794,292

(22) PCT Filed: Jan. 21, 2021
(86) PCT No.: PCT/FR2021/050107

§ 371 Date: Jul. 21, 2022

(30) Foreign Application Priority Data
Jan. 21, 2020 (FR) 2000573

(51) Int. Cl. H05K 7/20; H01M 10/613; H01M 10/6567

(52) U.S. Cl. CPC H05K 7/20272; H01M 10/613; H01M 10/6567

(57) ABSTRACT

The invention relates to a thermal management device for the thermal management of an electrical and/or electronic component liable to release heat during its operation, said device including a casing, said casing having a main compartment defining at least one housing able to accept said electrical and/or electronic component, said housing being designed to receive a dielectric fluid and being delimited by at least one wall. The wall includes a partition defining within the housing a first and a second chamber of dielectric fluid, said partition including an opening that is arranged in such a way that, when the electrical and/or electronic component is placed in the housing, this electrical and/or electronic component extends on both sides of said partition so that this electrical and/or electronic component extends into both of the two chambers.

### CROSS-REFERENCE TO RELATED APPLICATIONS

This application is filed under 35 U.S.C. § 371 U.S. National Phase of International Application No. PCT/FR2021/050107 filed Jan. 21, 2021 (published as WO2021160948), which claims priority benefit to French application No. 2000573 filed on Jan. 21, 2020, the disclosures of which are herein incorporated by reference in their entirety.

### TECHNICAL FIELD

The present invention relates to the field of devices for thermal regulation of electrical and/or electronic components that are liable to release heat during operation.

### BACKGROUND OF THE INVENTION

Electrical and/or electronic components, whether they are electrical energy storage cells, integrated circuits, servers, data centers, etc., require thermal regulation in order to keep them within their operating temperature range.

Data centers around the world currently account for 10% of global electricity consumption. The advent of “blockchain” and 5G technologies means that this percentage could increase drastically in the coming years. At least half of this consumption comes from the cooling systems of these data centers. Currently, most data centers are air-cooled by cooling the ambient air in storage rooms with air conditioning devices. The optimum operating temperature for data centers is between 5° C. and 40° C., more specifically around 27° C. Taking into consideration that air has a very low conductivity, in order to sufficiently cool the electrical and/or electronic components, which can reach temperatures exceeding 60° C., the temperature difference between the air and the electrical and/or electronic components to be cooled must be great and therefore this type of device is very energy intensive.

In the automotive field, for example, it is a known practice to use electric batteries in the form of electronic modules liable to release heat during operation. Each module can have a plurality of electronic cells that are capable of releasing heat during operation and are accommodated in a casing. High-density energy storage cells such as Li-ion or Li-polymer batteries ideally need to operate in a temperature range of between 20° C. and 40° C., and a temperature that is too low has an impact on their autonomy while a temperature that is too high has an impact on their service life.

The various battery cells of an electrical storage system in particular can be cooled by means of a cold plate, inside which a cooling fluid circulates, with the plate being in contact with the battery cells to be cooled. It has been found that such heat exchangers can result in non-homogeneous cooling of the electric batteries of one and the same electrical storage system, which then results in a reduction in the performance capabilities of these electric batteries. These heat treatment devices also exhibit high thermal resistance because of the material thicknesses present between the cooling fluid and the battery cells, another parameter that contributes to high thermal resistance being the contact between the cooling plates, the thermal interfaces (PAD) and the surfaces of the cells.

For the purpose of providing a solution to these various problems, multiple devices are known.

Document FR3037727, which discloses a device for cooling the electric batteries of electric or hybrid cars, is known in particular. More specifically, this document relates to a device for cooling the cells of the electric batteries of a battery pack of the lithium-ion type. It comprises a hermetically sealed casing in which a dielectric fluid circulates. The electrical storage cells are partially submerged in the dielectric fluid in such a way as to ensure the heat exchange between the cells and the dielectric fluid. Thus, the electric batteries are cooled by immersing the cells of the electric batteries in said fluid. An additional deformable reserve of dielectric fluid consists of a tank located outside the casing and makes it possible to limit the pressure variations owing to the temperature variations of the fluid.

However, the complete immersion of the electrical storage cells in a fluid requires a large volume of fluid sensitive to the variations in inclination occurring for example during the transport of said devices or, if it is mounted in a vehicle, when said vehicle is moving.

The objective of the invention is to offer an alternative for thermal management of electrical and/or electronic components liable to release heat during operation by at least partially overcoming the aforementioned problems of the prior art, thus optimizing the service life and the performance capability of such an electrical and/or electronic component. The invention can advantageously be used in the automotive field for, for example, thermally regulating a power electronics element or an electrical energy storage element, or else in the field of data centers for cooling servers and other electronic elements.

### BRIEF SUMMARY OF THE INVENTION

More particularly, the invention relates to a thermal management device for thermal management of an electrical and/or electronic component liable to release heat during its operation, said device comprising a casing, said casing comprising a main compartment defining at least one housing able to accommodate said electrical and/or electronic component, said housing being arranged to receive a dielectric fluid and being delimited by at least one wall, characterized in that said wall comprises a partition defining, in the housing, a first dielectric fluid chamber and a second dielectric fluid chamber, said partition comprising an aperture arranged such that, when the electrical and/or electronic component is placed in the housing, this electrical and/or electronic component extends on both sides of said partition in such a way that this electrical and/or electronic component extends into both chambers.

Thus, by virtue of the invention, the fact that the electrical and/or electronic component extends in two chambers of dielectric fluid makes it possible, when the housing is inclined with respect to a horizontal plane, to keep a certain quantity of fluid in the two chambers, making it possible to cool the electrical and/or electronic component efficiently. Without such a subdivision into two chambers, in the event of inclination of the housing, the dielectric fluid could end up accumulated in a restricted area of the housing on only one side, causing poor cooling of the electrical and/or electronic component. In other words, the presence of two chambers makes it possible to maintain a great degree of contact between the electrical and/or electronic component and the dielectric fluid, even when the housing is inclined. Moreover, the subdivision into different chambers makes it possible to limit the movement of the dielectric fluid and consequently limits the free surface effect, for example if the device is in motion, for example mounted in a vehicle.

Throughout the description, the terms “lateral”, “longitudinal” and “vertical” refer to an arbitrary orientation of a thermal management device according to the invention in an orthonormal reference system Oxyz. Thus, a “longitudinal” direction corresponds to a direction parallel to an axis Oz, a “lateral” direction corresponds to a direction parallel to an axis Ox, and a “vertical” direction corresponds to a direction parallel to an axis Oy.

The terms “horizontal plane” refer here to a plane perpendicular to the direction of gravity, in particular represented in the present description by the levels of dielectric fluid. The terms “cross section” for their part refer to sections made through a plane, referred to as transverse plane, parallel to the plane Oxz in which is inscribed the lateral axis Ox and the longitudinal axis Oz. The terms “lateral section” for their part refer to sections made through a plane, referred to as vertical plane, parallel to the plane Oxy in which is inscribed the lateral axis Ox and the vertical axis Oy. The terms “longitudinal section” for their part refer to sections made through a plane, referred to as longitudinal plane, parallel to more Ozy in which is inscribed the longitudinal axis Oz and the vertical axis Oy.

The cooling device advantageously comprises at least any one of the following features, taken individually or in combination, at the very least if the combination is technically feasible.

The aperture is intended to complement an outer perimeter of the electrical and/or electronic component. Thus, once joined with an electrical and/or electronic component, the aperture of the partition is closed by said electrical and/or electronic component; the first and second chambers are therefore fluidically isolated from one another. In other words, once mounted inside the housing, the electrical and/or electronic component together with the partition ensures sealing between the first chamber and the second chamber.

The partition comprises a sealing lip, advantageously at the aperture and intended to come into contact with the outer perimeter of the electrical and/or electronic component, and a partition body located between the wall to which the partition is attached and the sealing lip.

The sealing lip is made from a material different from the partition body, advantageously a deformable material, in particular an elastomer, so as to closely follow the shape of an outer surface of the electrical and/or electronic component. Thus, the partition has a first part, the partition body, made of a material exhibiting sufficient resistance to the pressure of the fluid in the chamber, advantageously it is the same material as the main compartment, and a second, flexible part for adapting to the contour of the electrical and/or electronic component and exhibiting sufficient tolerance to deformation to facilitate the mounting and maintain constant contact between the sealing lip and the electrical and/or electronic component.

The sealing lip forms a flexible seal intended to provide the sealing between the partition and the electrical and/or electronic component.

The partition and the wall are formed in one piece. In this case, the main compartment is formed in one piece, in particular formed by molding.

The partition is overmolded onto the wall.

The partition is a fitted part interacting with the fixing elements of the wall allowing the wall and the partition to be joined in a dielectric-fluid-tight manner. For example, a channel is formed in the wall into which the wall is slid, advantageously a seal is inserted into this channel to ensure the sealing; the partition can also be adhesively bonded, welded or screwed to the wall.

The main compartment comprises a base wall from which emerges at least a first and a second longitudinal wall and a first and a second lateral wall, thus making it possible to define an internal volume. The transverse plane of the device is then a plane parallel to a plane in which is inscribed the intersection of the base wall and the longitudinal walls and/or the lateral walls.

The main compartment comprises a plurality of housings, two consecutive housings being separated from one another by a longitudinal wall.

A longitudinal wall seals off the two consecutive housings that it separates, such that it is not possible for dielectric fluid to pass from one housing to the other through this wall. The main compartment is thus subdivided into sub-compartments that are advantageously mutually sealed and form the housings.

Each housing comprises a partition, advantageously each housing has the same configuration.

A housing is formed by the base wall, the lateral walls and two longitudinal walls of the main compartment.

The partition forming a projection on the base wall, and/or one or more longitudinal walls, and/or one or more lateral walls.

The partition has a thickness d1 defined by two opposite outer faces of said partition, said thickness d1 being less than a width c1 of a dielectric fluid chamber, the width c1 being taken between an outer face of the partition and a wall of the housing extending parallel to said partition. Advantageously, the thickness d1 has a ratio d1/c1 of between 0.1 and 0.0001, in particular 0.05 and 0.0005 relative to the width c1.

The housing comprises at least one dielectric fluid inlet orifice. Thus, each housing can be supplied individually with dielectric fluid.

The housing comprises a dielectric fluid inlet orifice.

The housing comprises one inlet orifice and/or one outlet orifice per circulation chamber.

The inlet orifice of the first chamber and the outlet orifice of the second chamber are positioned on the first lateral wall, and the outlet orifice of the first chamber and the inlet orifice of the second chamber are formed on the second lateral wall. Thus, the direction of circulation of dielectric fluid in the first chamber is opposite to the direction of circulation of dielectric fluid in the second chamber.

The partition comprises a second aperture so as to allow the circulation of fluid between the first and second chambers, advantageously the second aperture is formed in a part of the partition that is located between the first aperture and the first lateral wall, advantageously in the partition body. Advantageously, the inlet orifice and the outlet orifice of the housing are located on the second lateral wall facing the second aperture, the inlet orifice leading into the first chamber and the outlet orifice leading into the second chamber, thus allowing the dielectric fluid to circulate in a U shape within the housing.

The inlet orifice(s) are fluidically connected and supplied by a supply duct. Advantageously, the inlet orifices in the first lateral wall are connected to one and the same supply duct, whereas the inlet orifices in the second lateral wall are connected to a second supply duct.

Each chamber at least partially surrounds the electrical and/or electronic component, and in particular in contact with at least two faces of the electrical and/or electronic component such that the fluid in each chamber can come into contact with two faces of the electrical and/or electronic component.

The outlet orifice(s) are fluidically connected to a discharge duct. Advantageously, the outlet orifices in the first lateral wall are connected to one and the same discharge duct, whereas the outlet orifices in the second lateral wall are connected to a second discharge duct.

The inlet orifice(s) are positioned on a top part of the device, advantageously on a lateral wall close to the cover or on the cover.

The supply and discharge ducts are connected to an external circuit for circulation of the dielectric fluid.

The fluid outlet orifice(s) are located at a bottom point, or bottom region, so as to make it easier to discharge the fluid from a housing.

The base wall comprises at least one section which is inclined with respect to the transverse plane of the device, the base wall thus having what is referred to as a top region, and what is referred to as a bottom region, the top region being above the bottom region when the transverse plane of the device is parallel to a horizontal plane. Advantageously, a fluid outlet orifice is located in the bottom region of the base wall, thus the base wall is configured to make it easier to discharge the dielectric fluid through the outlet orifice, making it possible for example to facilitate the emptying of a housing.

In the base wall, each housing comprises an outlet orifice in the bottom region shared by the two dielectric fluid chambers. In other words, the outlet orifice leads into the first chamber and into the second chamber on either side of the partition. The outlet orifice is therefore positioned at the intersection between the base wall and the partition of a housing.

The base wall comprises a fluid discharge bowl, the bowl having said at least one fluid outlet orifice, and a wall which is curved up to said at least one outlet orifice, the curved wall comprising said at least one inclined section.

The base wall comprises two sections inclined with respect to the transverse plane of the device, the inclined sections meeting at one end in a top region, the bottom regions therefore being located at a second end of the sections, opposite the first end of each section. Advantageously, the bottom regions are formed at the intersection between the second ends of the inclined sections and the lateral and/or longitudinal walls.

The base wall comprises two sections inclined with respect to the transverse plane of the device, the inclined sections meeting at one end in a bottom region, the top regions therefore being located at a second end of the sections, opposite the first end of each section. Advantageously, the top regions are formed at the intersection between the second ends of the inclined sections and the lateral and/or longitudinal walls.

Each housing comprises a volume of dielectric fluid.

The casing comprises a cover intended to close the main compartment.

The partition at least partially surrounds the electrical and/or electronic component, and is in particular in contact with at least two faces of the electrical and/or electronic component such that the fluid in each chamber can come into contact with two faces of the electrical and/or electronic component.

The cover comprises a second partition contributing to the delimitation of the first and second fluid circulation chambers. The second partition also complements a perimeter of the electrical and/or electronic component, advantageously, once joined, the second partition is in contact with the first partition, or partition of the main compartment.

The second partition also complements a perimeter of the electrical and/or electronic component, advantageously, once joined, the second partition is in contact with the first partition, or partition of the main compartment.

The first partition has a portion, the second partition has a portion; once the cover is joined to the main compartment, the portions of the first and second partitions are in contact so as to form a single partition completing the contour of the electrical and/or electronic component.

The casing is formed by a composite material, in particular a polymer material reinforced with fibers, in particular metal, carbon or glass fibers.

The partition also forms a support for the electrical and/or electronic component.

The dielectric fluid is a dielectric liquid.

The dielectric fluid is characterized by an evaporation point which falls within an optimum operating temperature range of the electrical and/or electronic component, for example at 20 and 40° C.; in this way, if the electrical and/or electronic component exceeds this temperature, the fluid in contact with it vaporizes and allows improved removal of heat energy in comparison with a single-phase dielectric fluid.

The dielectric fluid is cooled and/or heated by at least one exchanger external to the thermal management device.

The thermal management device comprises a heat exchanger intended to cool and/or heat the dielectric fluid.

The housing comprises a plurality of supports, in particular in the form of piles, bearing against or extending from the base wall. Thus, the electrical and/or electronic component is at a sufficient distance from the base wall allowing the heat transfer fluid to be in contact with a perimeter of the electrical and/or electronic component facing the base wall.

The invention also relates to an electrical and/or electronic component assembly comprising a thermal management device as described according to one of the embodiments above and at least one electrical and/or electronic component liable to release heat during operation.

The features, variants and various embodiments of the invention can be combined with one another, in various combinations, provided that they are not mutually incompatible or exclusive. It can be possible in particular to contemplate variants of the invention that comprise only a selection of features described in the present description, in isolation from the other features described, if this selection of features is sufficient to confer a technical advantage.

### BRIEF DESCRIPTION OF THE DRAWINGS

Further features and advantages of the invention will become more clearly apparent both from the following description and from a number of exemplary embodiments, which are provided by way of nonlimiting indication with reference to the appended schematic drawings, in which:

FIG. 1 schematically illustrates a view in cross section of a thermal management device according to one of the embodiments of the invention,

FIG. 2 schematically illustrates a view in longitudinal section of a thermal management device according to one of the embodiments of the invention,

FIG. 3 schematically illustrates a view in lateral section of the thermal management device according to one of the embodiments of the invention, for which the transverse plane of the device is parallel to a horizontal plane,

FIG. 4 schematically illustrates a sectional view in lateral section of the thermal management device according to one embodiment of the invention, for which the transverse plane of the device intersects a horizontal plane,

FIG. 5a schematically illustrates a sectional view in longitudinal section of the thermal management device according to one embodiment of the invention, and

FIG. 5b schematically illustrates a sectional view in longitudinal section of the thermal management device according to another embodiment of the invention.

### DETAILED DESCRIPTION OF THE INVENTION

In the figures, elements that are common to multiple figures retain the same reference.

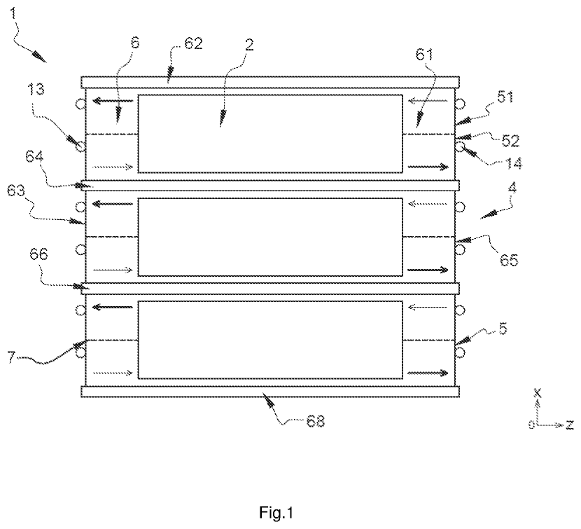

FIG. 1 schematically illustrates a thermal management device 1 according to the invention. The thermal management device 1 comprises a casing 3 comprising a main compartment 4 delimited by a first longitudinal wall 62 and a second longitudinal wall 68, a first lateral wall 63 and a second lateral wall 65, and a base wall 61. The main compartment 4 also comprises a third longitudinal wall 64 and a fourth longitudinal wall 66 so as to define three housings 5 separated from one another by a longitudinal wall 64, 66 and each accommodating an electrical and/or electronic component 2, said housings 5 being arranged to accommodate a dielectric fluid and comprise a wall 6. Said wall 6 comprises a first partition 7 defining, in a housing, a first dielectric fluid chamber 51 and a second dielectric fluid chamber 52. Each first partition 7 extends over the base wall 61 of the main compartment 4, a first lateral wall 63 and a second lateral wall 65.

In the embodiment illustrated here, each dielectric fluid chamber 51, 52 comprises a dielectric fluid inlet orifice 13 and a dielectric fluid outlet orifice 14. The dielectric fluid inlet orifice 13 of the first chamber 51 and the dielectric fluid outlet orifice 14 of the second chamber 52 are positioned on the first lateral wall 65, and the dielectric fluid outlet orifice 14 of the first chamber 51 and the dielectric fluid inlet orifice 13 of the second chamber 52 are formed on the second lateral wall 63. Thus, the direction of circulation of dielectric fluid in the first chamber 51 is opposite to the direction of circulation of dielectric fluid in the second chamber 52.

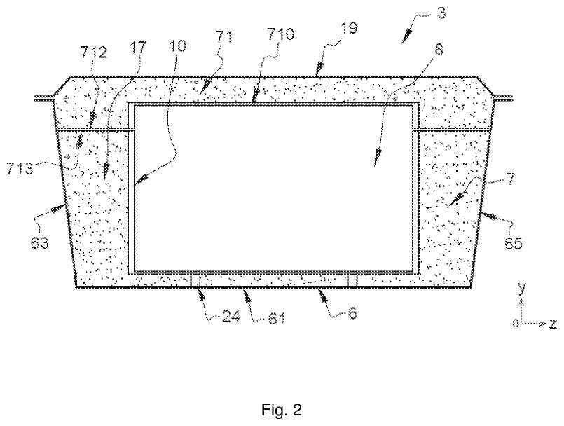

FIG. 2 schematically illustrates a view in longitudinal section of a thermal management device 1 according to the invention. In the example illustrated, said first partition 7 comprises an aperture 8 arranged such that, when the electrical and/or electronic component 2 (not shown in this FIG. 2) is placed in the housing 5, this electrical and/or electronic component 2 extends on both sides of said first partition 7 in such a way that this electrical and/or electronic component 2 extends in the two chambers 51, 52. The aperture 8 is intended to complement an outer perimeter 9 of the electrical and/or electronic component 2. For the sake of simplicity of representation, the electrical and/or electronic component 2 is shown in FIGS. 1 to 5 as a parallelepipedal element. However, invention applies also to any type of cylindrical or spherical shape. A person skilled in the art can easily deduce the shape of the aperture 8 from the shape of the perimeter or contour 9 of the electrical and/or electronic component 2 intended to be mounted in a housing 5 of the thermal management device 1.

The first partition 7 comprises a first sealing lip 10 at the aperture 8, intended to come into contact with and closely follow the shape of the outer perimeter 10 of the electrical and/or electronic component 2. The first sealing lip 10 can be made from a different material from the rest of the first partition 7, referred to as partition body 17. Advantageously, the first sealing lip 10 is composed of a deformable material, in particular an elastomer, so as to closely follow the shape of the perimeter of the electrical and/or electronic component 2. Thus, the first sealing lip 10 forms a flexible seal intended to ensure the sealing between the first partition 7 and the electrical and/or electronic component 2; once mounted inside the housing 5, the electrical and/or electronic component 2 together with the partition 7 ensures the sealing between the first chamber 51 and the second chamber 52.

The casing 3 comprises a cover 19 intended to close the main compartment 4. The cover 19 comprises a second partition 71 contributing to the delimitation of the first dielectric fluid chamber 51 and second dielectric fluid chamber 52, the second partition 71 also having a second sealing lip 710. The second partition 71 also complements a perimeter of the electrical and/or electronic component 2. Advantageously, once joined, the second partition is in contact with the first partition 7, or partition of the main compartment 4. The first partition 7 has a portion 713, the second partition 71 has a portion 712; once the cover 19 is joined to the main compartment 4, the portions of the first partition 7 and second partition 71 are in contact so as to form a single partition completing the contour of the electrical and/or electronic component 2.

The housing 5 comprises a plurality of supports 24, in particular in the form of piles, bearing against or extending from the base wall 61. Thus, the electrical and/or electronic component 2 is at a sufficient distance from the base wall 61 allowing the heat transfer fluid to be in contact with a perimeter of the electrical and/or electronic component 2 facing the base wall 61.

In the example illustrated, in particular FIGS. 1, 3 and 4, the main compartment 4 comprises a base wall 61 from which emerges at least a first, a second, a third and a fourth longitudinal wall 62, 68, 64 and 66, and a first and a second lateral wall 63, 65. In this instance, the partition 7 can be overmolded onto the base wall 61 and the first and second lateral walls 63 and 65. The main compartment 4 comprises a plurality of housings 5, two consecutive housings 5 being separated from one another by a longitudinal wall 64, 66. A longitudinal wall 64, 66 seals off the two consecutive housings that it separates, such that it is not possible for dielectric fluid to pass from one housing to the other through this longitudinal wall 64, 66. Thus, a housing 5 is formed by the base wall 51, the first and second lateral walls 63, 65 and two longitudinal walls 62, 68, 64, 66 of the main compartment 4. The partition 7 forms a projection on the base wall 61 and the lateral walls 63, 65.

In the example illustrated, each chamber 51, 52 at least partially surrounds the electrical and/or electronic component 2, and in particular in contact with at least two faces of the electrical and/or electronic component 2 such that the fluid in each chamber 51, 52 can come into contact with two faces of the electrical and/or electronic component 2.

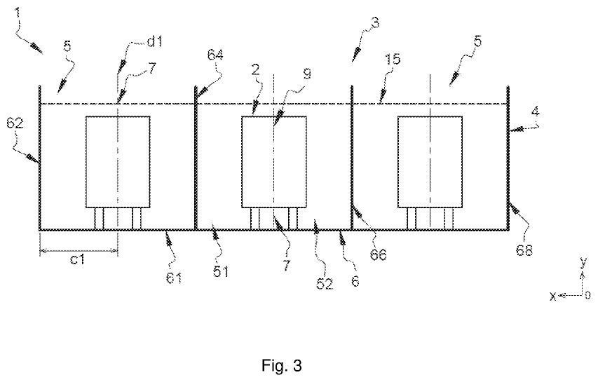

FIG. 3 shows a view in lateral section of the thermal management device 1 when the transverse plane of the thermal management device 1 is parallel to a horizontal plane. The first partition 7 has a thickness d1 defined by two opposite outer faces of said first partition 7, said thickness d1 being less than a width c1 of a dielectric fluid chamber 51, 52, the width c1 being taken between an outer face of the first partition 7 and a longitudinal wall 62 of the housing 5 extending parallel to and facing said outer face of the partition 7. Advantageously, the thickness d1 has a ratio d1/c1 of between 0.1 and 0.0001, in particular 0.05 and 0.0005 relative to the width c1.

In order to allow homogeneous thermal management of the electrical and/or electronic component 2, each housing 5 is filled with dielectric fluid until the electrical and/or electronic component 2 is completely immersed, such that the level of dielectric fluid 15 is above the electrical and/or electronic component 2 when the thermal management device 1 is horizontal, that is to say when the transverse plane of the thermal management device 1 is parallel to a horizontal plane.

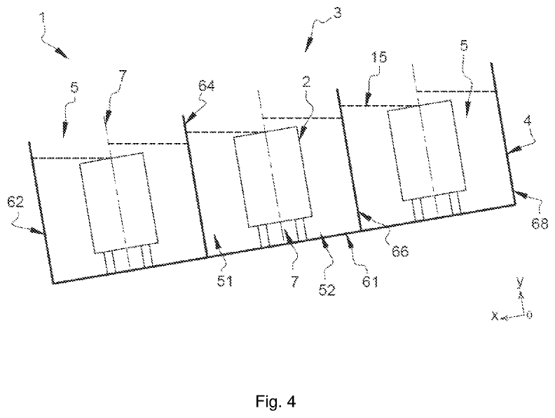

FIGS. 3 and 4 make it possible to illustrate the effects of the invention. Specifically, FIG. 4 shows that even when the thermal management device 1 is no longer horizontal, the electrical and/or electronic component 2 remains immersed in such a way that, if it is subjected to significant stress resulting in a need for significant heating or cooling, since the electrical and/or electronic component 2 remains immersed the heat exchange is still homogeneous.

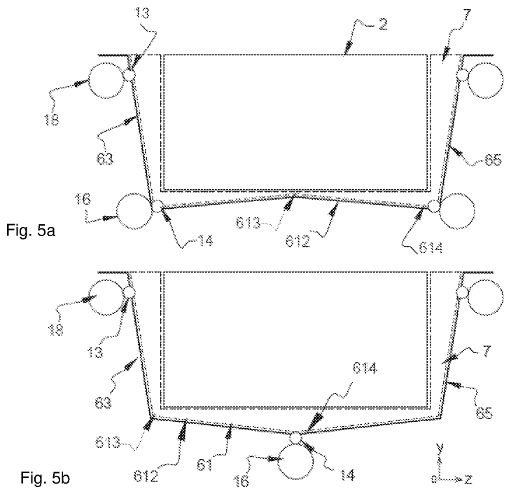

In FIG. 5a, the base wall 61 comprises two sections 612 inclined with respect to the transverse plane of the thermal management device 1. The base wall 61 thus has what is referred to as a top region 613, and what is referred to as a bottom region 614, the top region 613 being above the bottom region 614 when the transverse plane of the thermal management device 1 is parallel to a horizontal plane. Since the inclined sections 612 meet at one end in a top region 613, the bottom regions 614 are therefore located at a second end of the sections 612, opposite the first end of each section 612. Advantageously, the bottom regions 614 are formed at the intersection between the second ends of the inclined sections 612 and the lateral walls 63, 65 and/or longitudinal walls 62, 64, 66, 68.

Advantageously, the fluid outlet orifices 14 are located in the bottom region 614 of the base wall 61, thus the base wall 61 is configured to make it easier to discharge the dielectric fluid through the dielectric fluid outlet orifice 14, making it possible for example to facilitate the emptying of a housing 5.

In the embodiment illustrated in FIGS. 5a and 5b, each chamber 51, 52 has its own dielectric fluid inlet orifice 13. The dielectric fluid inlet orifice 13 of the first chamber 51 is borne by the lateral wall 65 and connected to a supply duct 18; the dielectric fluid inlet orifice 13 of the second chamber 52 is borne by the lateral wall 63 and connected to another supply duct 18.

The base wall 61 has two bottom regions 614 and each chamber 51, 52 comprises an outlet orifice. The dielectric fluid outlet orifice 14 of a chamber 51, 52 being positioned in the bottom region 614 close to the lateral wall that faces the lateral wall bearing the dielectric fluid inlet orifice 13 of the chamber 51, 52.

Each chamber 51, 52 has its own dielectric fluid outlet orifice 14. The dielectric fluid outlet orifice 14 of the first chamber 51 is borne by the lateral wall 63 and connected to a discharge duct 16; the dielectric fluid outlet orifice 14 of the second chamber 52 is borne by the lateral wall 65 and connected to another discharge duct 16.

The supply ducts 18 and discharge ducts 16 are connected to an external circuit for circulation of the dielectric fluid.

In FIG. 5b, in the base wall 61, each housing 5 comprises a dielectric fluid outlet orifice 14 in the bottom region 613 shared by the two dielectric fluid chambers 51, 52. In other words, the dielectric fluid outlet orifice 14 leads both into the first chamber 51 and into the second chamber 52 on either side of the partition 7. The dielectric fluid outlet orifice 14 is therefore positioned at the intersection between the base wall 61 and the partition of a housing 7. Moreover, the base wall 61 comprises two sections 612 inclined with respect to the transverse plane of the thermal management device 1, the inclined sections 612 meeting at one end in a bottom region 614, the top regions 613 therefore being located at a second end of the sections 612, opposite the first end of each section 612. Advantageously, the top regions 613 are formed at the intersection between the second ends of the inclined sections 612 and the lateral and/or longitudinal walls.

The representations of FIGS. 1 to 5 are schematic. The present invention also covers different embodiments, in particular on account of the shape of the housing and/or of the reservoir.

However, the invention should not be considered to be limited to the means and configurations described and illustrated herein, and it also extends to all equivalent means or configurations and to any technically operational combination of such means. In particular, the number of walls and the presence of a heat transfer fluid circuit can be modified without having an adverse effect on the invention, provided that the thermal management device 1 ultimately fulfils the same functionalities as those described in the present document.

What is claimed is:

1. A thermal management device for thermal management of a component liable to release heat during its operation, said thermal management device comprising a casing, said casing including a main compartment defining at least one housing able to accommodate said component, said at least one housing being arranged to accommodate a dielectric fluid and being delimited by at least one wall, wherein said at least one wall includes a partition defining, in the at least one housing, a first dielectric fluid chamber and a second dielectric fluid chamber, said partition including first aperture arranged such that, when the component is placed in the at least one housing, the component extends on both sides of said partition into both chambers.

2. The thermal management device as claimed in claim 1, wherein the first aperture complements an outer perimeter of the component when the component is placed in the at least one housing.

3. The thermal management device as claimed in claim 1, wherein the partition includes a first sealing lip, and a partition body located between the at least one wall to which the partition is attached and the first sealing lip.

4. The thermal management device as claimed in claim 1, wherein the main compartment includes base wall from which emerge at least a first and a second longitudinal wall and a first and a second lateral wall.

5. The thermal management device as claimed in claim 1, wherein the main compartment includes a plurality of housings, two consecutive housings being separated from one another by a longitudinal wall.

6. The thermal management device as claimed in claim 1, wherein the at least one housing includes at least one dielectric fluid inlet orifice and one dielectric fluid outlet orifice.

7. The thermal management device as claimed in claim 1, wherein the partition includes a second aperture so as to allow the circulation of fluid between the first and second chambers.

8. The thermal management device as claimed in claim 7, wherein at least one dielectric fluid inlet orifice and at least one dielectric fluid outlet orifice of the at least one housing are located on the second lateral wall facing the second aperture, the at least one dielectric fluid inlet orifice leading into the first chamber and the at least one dielectric fluid outlet orifice leading into the second chamber, thus allowing the dielectric fluid to circulate in a U shape within the at least one housing.

9. The thermal management device as claimed in claim 4, wherein the base wall includes at least one section inclined with respect to a transverse plane of the thermal management device, the base wall thus having a top region and a bottom region, the top region being above the bottom region when the transverse plane of the thermal management device is parallel to a horizontal plane.

10. The thermal management device as claimed in claim 1, wherein the casing includes a cover intended to close the main compartment.

11. The thermal management device as claimed in claim 1, wherein the at least one housing includes at least one dielectric fluid inlet orifice or one dielectric fluid outlet orifice.

12. The thermal management device according to claim 3, wherein the first sealing lip is arranged at the first aperture and intended to come into contact with the outer perimeter of the component.

13. The thermal management device according to claim 5, wherein the consecutive housings are separated in a sealed manner.

14. The thermal management device according to claim 7, wherein the main compartment includes a base wall from which emerge at least a first and a second longitudinal wall and a first and a second lateral wall, the second aperture being formed in a part of the partition that is located between the first aperture and the first lateral wall.

15. The thermal management device according to claim 9, wherein a fluid outlet is located in the bottom region of the base wall.

16. The thermal management device according to claim 10, wherein the cover includes a second partition contributing to the delimitation of the first and second fluid circulation zones.
